(19) United States
(12) Patent Application Publication
(10) Pub. No.: US 2007/0103179 A1
(43) Pub. Date: May 10, 2007

(54) SOCKET BASE ADAPTABLE TO A LOAD BOARD FOR TESTING IC

(75) Inventors: SHOU-NAN TSAI, HSIN-CHU (TW); MU-SHENG LIAO, HSIN-CHU (TW)

Correspondence Address: SQUIRE, SANDERS & DEMPSEY L.L.P, PATENT DEPARTMENT, ONE MARITIME PLAZA, SUITE 300, SAN FRANCISCO, CA, 94111-3492, US

(73) Assignee: SILICON INTEGRATED SYSTEMS CORP., Hsin-Chu (TW)

(21) Appl. No.: 11/164,104

(22) Filed: Nov. 10, 2005

(51) Int. Cl. G01R 31/02

(52) U.S. Cl. 324/755

(57) ABSTRACT

A socket base adaptable to a load board for testing semiconductor devices is disclosed. The socket base includes a first fixing element having coupling plates, a probe element, and a second fixing element, which are detachable and combinable. Accordingly, the procedure for replacing the probe element is simplified, time is reduced, and efficiency is increased.

### FIELD OF THE INVENTION

The present invention generally relates to a socket base adaptable for a load board, and more particularly to a detachable and combinable socket base for testing semiconductor devices.

### DESCRIPTION OF THE PRIOR ART

The advancement of the integrated circuits manufacturing technique brings abundant electronic products to our modern life. In addition to attaining more compact electronic products, diverse integrated circuits are simultaneously applied into a single product to obtain more functions. In order to accomplish this goal, the quality of each integrated circuit is predominantly important.

The manufacture of the integrated circuits passes through a series of strictly controlled steps. The circuit is firstly designed and applied to the manufacture of wafers, followed by cutting each manufactured wafer into chips. The chips are packaged and then tested to their functionality and reliability. The test is a critical step in which malfunctioned or defective chips/integrated circuits are screened out.

A probe element or prober is utilized in test equipment to contact the devices under test. One of the difficulties concerning the probe element in the conventional test equipment is the complex or time-consuming procedure to install or replace the probe element.

FIG. 1A shows conventional test equipment for testing ball grid array (BGA) integrated circuits. A robot arm 104 of a manipulator 102 lifts a test head 106 towards test apparatus 100. A load board 108 and a socket base 110 are positioned between the test head 106 and the test apparatus 100. The test apparatus 100, the socket base 110, and the load board 108 are secured together, for example, by screws before performing a test on semiconductor devices.

FIG. 1B shows a sectional view of the socket base 110 and the load board 108. The pick tool 114 of the test apparatus 100 picks up a semiconductor device 118 by using a vacuum head 116. The pick tool 114 secures and aligns to the socket base 110 by the guide pins 110a. The solder balls 118a of the semiconductor device 118 are contacted by a probe element 112, such as a surface mount matrix (SMM), which is further connected to the load board 108.

FIG. 1C shows a perspective view of the load board 108, the socket base 110, and the SMM 112 therebetween. The guide pins 110a are used for alignment with the test apparatus, and the guide pins 110b are used for alignment with the device under test. As shown in FIG. 1D, the test apparatus 100 is secured to the test head 106 by screws while performing the test. The socket base 110 could not easily be replaced without firstly separating the test apparatus 100 and the test head 106 whenever the SMM 112 becomes unclean.

Specifically, the screws are firstly loosened, and the test head 106 is lowered by the manipulator 102. Thereafter, the socket base 110 is removed from the load board 108, followed by cleaning the SMM 112. The SMM 112, the socket base 110, and the load board 108 are assembled in reverse steps.

For the reason that conventional replacement procedure is complex and time-consuming, a need has arisen to propose a new socket base that improves the efficiency of replacing the probe element.

### SUMMARY OF THE INVENTION

In view of the foregoing, it is an object of the present invention to provide a detachable and combinable socket base to simplify the replacement procedure of the probe element.

According to the object, the present invention provides a socket base adaptable to a load board for testing semiconductor devices. The socket base includes a first fixing element having an opening, first guide structures, and coupling plates; a second fixing element having first coupling structures, second guide structures; and a probe element having fixing pin holes. The first fixing element and the second fixing element are detachable and combinable by using the coupling plates. Accordingly, the procedure for replacing the probe element is simplified, consumed time is reduced, and efficiency is therefore increased.

### BRIEF DESCRIPTION OF THE DRAWINGS

FIGS. 1A to 1D show conventional equipment for testing ball grid array (BGA) integrated circuits;

FIG. 2 and FIG. 3 schematically show the composing elements of a socket base and the resultant socket base according to one embodiment of the present invention;

FIG. 4A and FIG. 4B show two exemplary disconnected second fixing elements of the present invention;

FIG. 5 schematically shows the composing elements of a socket base according to another embodiment of the present invention;

FIG. 6A and FIG. 6B show further two exemplary disconnected second fixing elements of the present invention;

FIG. 7A and FIG. 7B show two exemplary disconnected first fixing elements of the present invention; and

FIG. 8A and FIG. 8B show two examples of the first guide structure without using guide pins.

### DETAILED DESCRIPTION OF THE INVENTION

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

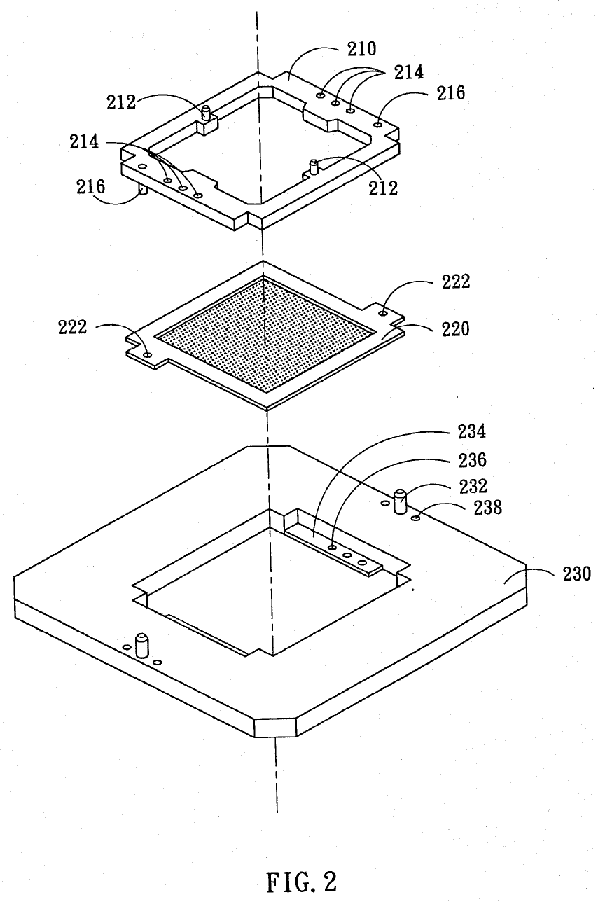

FIG. 2 schematically shows the composing elements of a socket base according to one embodiment of the present invention. A first fixing element 230 has an opening in the middle thereof, two first guide pins 232 acting as the first guide structures, and a coupling plate 234. A second fixing element 210 is used to secure a probe element 220, which is a surface mount matrix (SMM) 220 in this embodiment. On a first side (that is, the top side in the figure) of the second fixing element 210 are some second guide pins 212 acting as the second guide structures, and some first coupling holes 214 therethrough acting as the first coupling structures. On a second side (that is, the bottom side in the figure) of the second fixing element 210 are some fixing pins 216. The SMM 220 has some fixing pin holes 222 corresponding with the fixing pins 216. The coupling plate 234 of the first fixing element 230 has some second coupling holes 236 acting as the second coupling structures, which are aligned with the first coupling holes 214, so that the second fixing element 210 could be secured to the first fixing element 230. The first fixing element 230 also has some third coupling holes 238 which are used to secure the first fixing element 230 to a load board such as that designated as 108 shown in the previous drawings. It is appreciated that the first fixing element 230 could be configured in a shape other than that shown in the figure, and the number of the first guide pins 232 could be only one instead of two as shown.

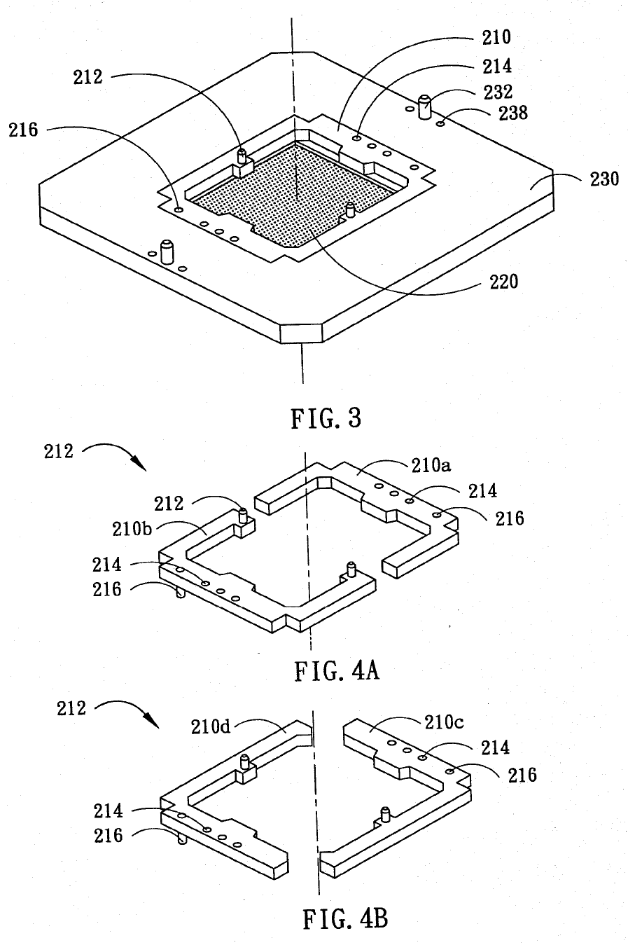

The pin holes 222 receive the fixing pins 216 of the second fixing element 210. Thereafter, the combined second fixing element 210 and probe element 220 is embedded in the opening of the first fixing element 230 and rests on the coupling plate 234. The three composing elements as shown are further secured by placing screws through the first coupling holes 214 and the corresponding second coupling holes 236, thereby resulting in the socket base adapted for a load board such as that shown in FIG. 3. Whenever the replacement of the SMM 220 is required, the screws are firstly loosened and the second fixing element 210 is then removed to reveal the SMM 220. This replacement procedure becomes substantially easier and faster compared to the conventional one.

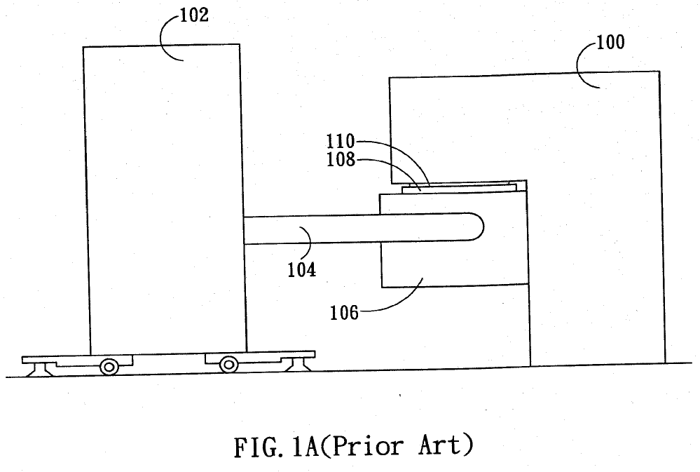

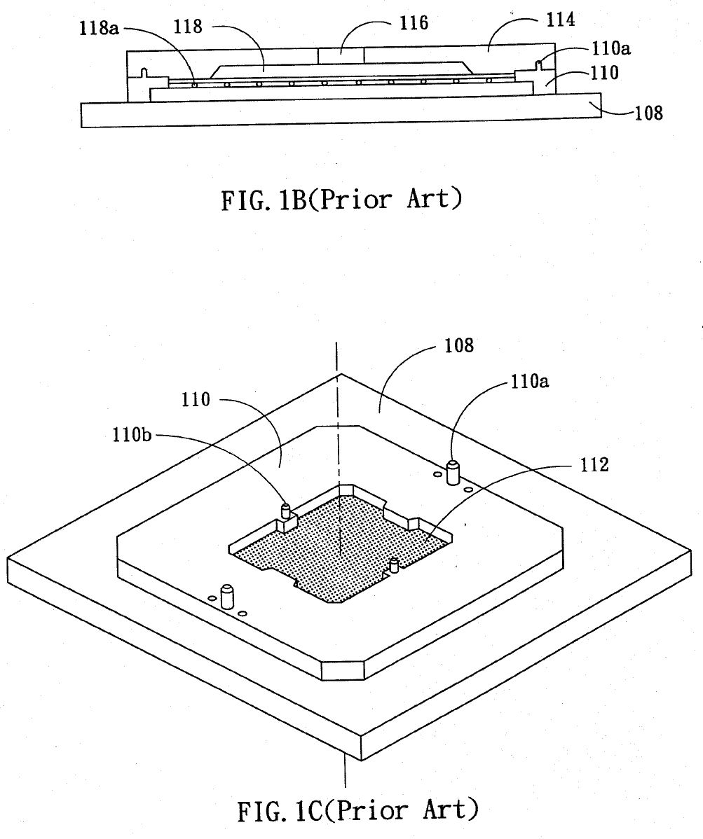

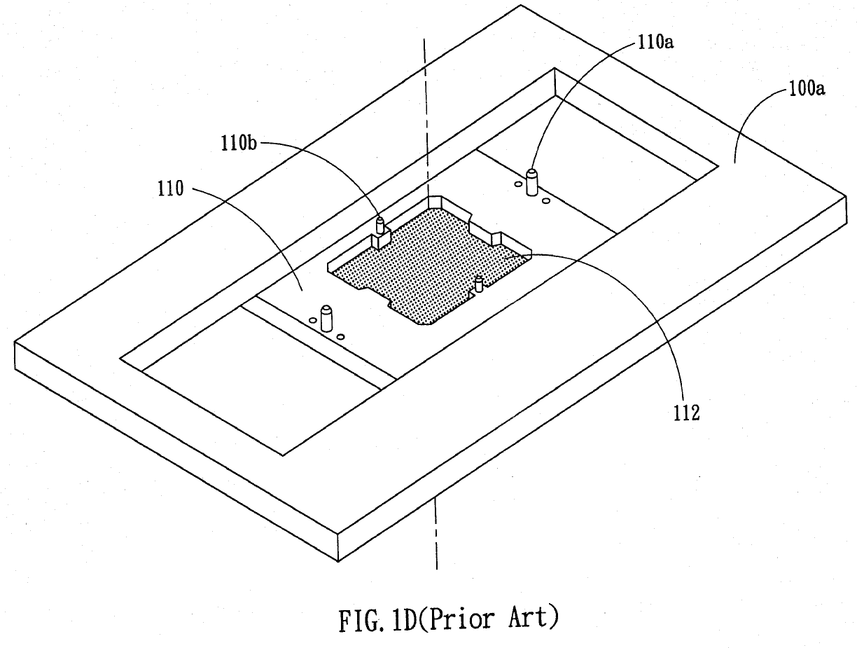

The first guide pins 232 on the first fixing element 230 are used for alignment with respect to test apparatus. The coupling plate 234 is extended along the peripheral of the opening, and has some (three in this example) second coupling holes 236, which are respectively corresponding to the first coupling holes 214. The third coupling holes 238 beside the first guide pin 232 are used to be secured to the load board (such as the load board 108 shown in FIGS. 1A-1C) by screws.

The second guide pins 212 on the second fixing element 210 are used for guiding or aligning a device under test. It is appreciated that the number of the second guide pins 212 is not limited to two, and the second guide pins 212 are preferably opposite to each other. Similarly, the number of the first coupling holes 214 is not limited to six, and the first coupling holes 214 are configured into two groups, which are preferably opposite to each other. Also, the number of the fixing pins 216 is not limited to two, and the fixing pins 216 are preferably opposite to each other.

The second fixing element 210 shown in FIGS. 2 and 3 has a close and connected shape, while in other embodiment, a disjoined second fixing element 210 could be used instead. FIG. 4A shows a disconnected second fixing element 212, which includes two U-shape parts 210a and 210b. Each part has three first coupling holes 214 and a fixing pin 216. The two second guide pins 212 could be located on one part 210b or could be respectively located on the two parts 210a and 210b. FIG. 4B shows another disconnected second fixing element 212, which includes two L-shape parts 210c and 210d. Each part has three first coupling holes 214, one fixing pin 216, and one second guide pin 212.

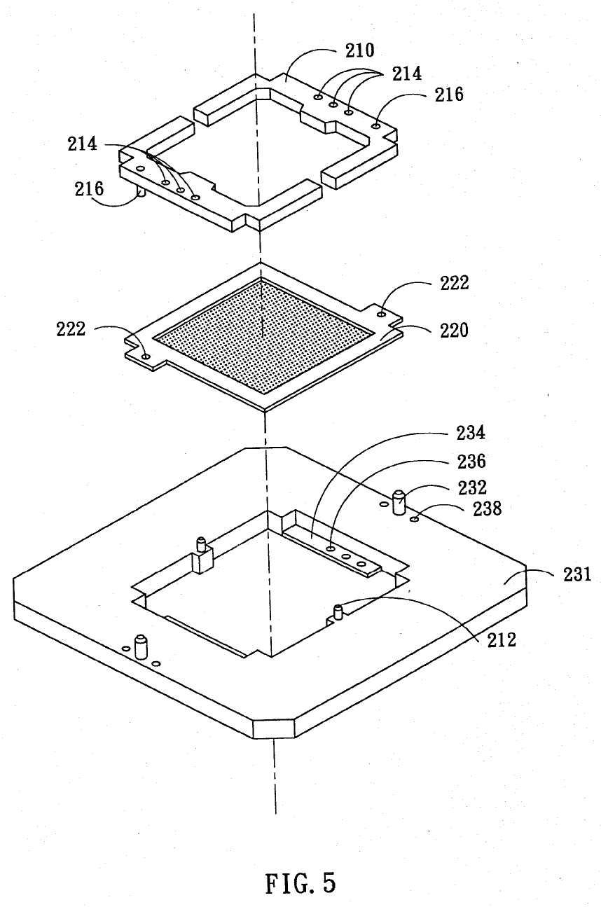

FIG. 5 schematically shows the composing elements of a socket base according to another embodiment of the present invention. Compared to FIG. 2, a disconnected second fixing element 210 including two parts is used, and this second fixing element 210 has no second guide pins thereon. Each part has some first coupling holes 214 and a fixing pin 216. The first fixing element 230 has some first guide pins 232 and the coupling plate 234, and further has the second guide pins 212. Besides, the coupling plate 234 has some second coupling holes 236, and the first fixing element 230 has some third coupling holes 238.

It is appreciated that the number of the first guide pins 232 and the second guide pins 212 is not respectively limited to two. The first guide pins 232 are preferably opposite to each other, and the second guide pins 212 are also preferably opposite to each other. Accordingly, these guide pins 232 and 212 are configured in a cross pattern.

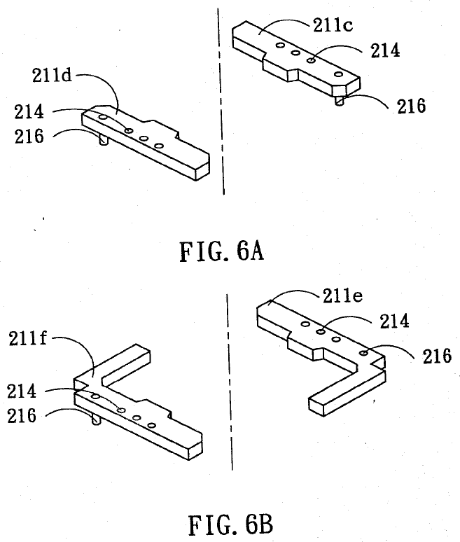

In addition to the second fixing element 210 having two U-shape parts demonstrated in FIG. 5, other second fixing element such as that shown in FIG. 6A or FIG. 6B could also be used instead. The second fixing element of FIG. 6A has two bar-shape parts 211c and 211d, and the second fixing element of FIG. 6B has two L-shape parts 211e and 211f.

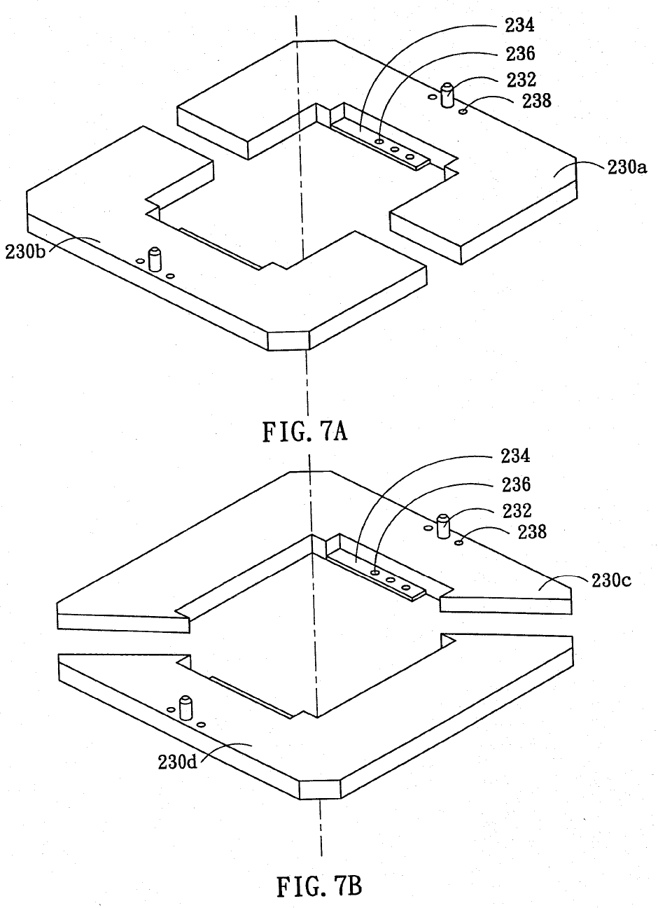

Moreover, a first fixing element having disconnected configuration could also be used. For example, the first fixing element of FIG. 7A has two U-shape parts 230a and 230b, and the first fixing element of FIG. 7B has two L-shape parts 230c and 230d.

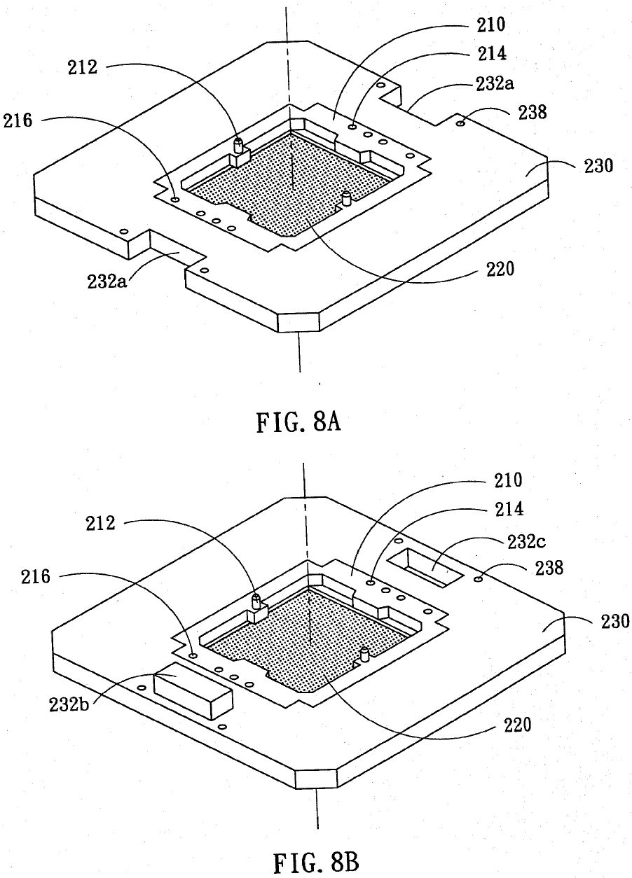

The first guide pins 232 as demonstrated in the previous drawings could be equivalently replaced by other means, such as the indentures 232a in FIG. 8A, or the protrusion 232b or the cave 232c.

Although specific embodiments have been illustrated and described, it will be appreciated by those skilled in the art that various modifications may be made without departing from the scope of the present invention, which is intended to be limited solely by the appended claims.

What is claimed is:

1. A socket base, which is secured to a load board, said socket base comprising:
a first fixing element, secured to the load board, said first fixing element having a coupling plate; and
a second fixing element, secured to said first fixing element.

2. The socket base of claim 1, further comprising a plurality of first coupling structures in said second fixing element.

3. The socket base of claim 2, further comprising a plurality of second coupling structures in the coupling plate.

4. The socket base of claim 1, further comprising a probe element located between said first fixing element and said second fixing element.

5. The socket base of claim 4, further comprising a plurality of fixing pin holes in said probe element.

6. The socket base of claim 5, further comprising a plurality of fixing pins under said second fixing element for securing said second fixing element and said probe element.

7. The socket base of claim 1, wherein said first fixing element further comprises a plurality of first guide structures.

8. The socket base of claim 7, wherein said second fixing element further comprises a plurality of second guide structures.

9. The socket base of claim 1, wherein said first fixing element further comprises a plurality of first guide structures and a plurality of second guide structures.

10. The socket base of claim 1, wherein said first fixing element has a connected shape.

11. The socket base of claim 1, wherein said first fixing element has a pair of disconnected parts.

12. The socket base of claim 1, wherein said second fixing element has a connected shape.

13. The socket base of claim 1, wherein said second fixing element has a pair of disconnected parts.

14. A test substrate, comprising:
a load board; and
a socket base including:
a first fixing element, secured to said load board, said first fixing element having a coupling plate; and
a second fixing element, secured to said first fixing element.

15. The test substrate of claim 14, further comprising a plurality of first coupling structures in said second fixing element.

16. The test substrate of claim 15, further comprising a plurality of second coupling structures in the coupling plate.

17. The test substrate of claim 14, further comprising a probe element located between said first fixing element and said second fixing element.

18. The test substrate of claim 17, further comprising a plurality of fixing pin holes in said probe element.

19. The test substrate of claim 18, further comprising a plurality of fixing pins under said second fixing element for securing said second fixing element and said probe element.

20. The test substrate of claim 14, wherein said first fixing element further comprises a plurality of first guide structures.

21. The test substrate of claim 20, wherein said second fixing element further comprises a plurality of second guide structures.

22. The test substrate of claim 14, wherein said first fixing element further comprises a plurality of first guide structures and a plurality of second guide structures.

23. The test substrate of claim 14, wherein said first fixing element has a connected shape.

24. The test substrate of claim 14, wherein said first fixing element has a pair of disconnected parts.

25. The test substrate of claim 14, wherein said second fixing element has a connected shape.

26. The test substrate of claim 14, wherein said second fixing element has a pair of disconnected parts.

27. The test substrate of claim 14, wherein said first fixing element further comprises third coupling structures for securing to said load board.

28. A socket base adaptable to a load board for testing semiconductor devices, comprising:
a first fixing element, having an opening, a plurality of first guide pins, and a plurality of coupling plates;
a second fixing element, having a plurality of fixing pins on a bottom side thereof, and a plurality of first coupling holes, wherein said second fixing element is secured to said first fixing element by the coupling plates; and
a surface mount matrix, having a plurality of fixing pin holes corresponding to the fixing pins, wherein said second fixing element is secured to said surface mount matrix by respectively inserting the fixing pins into the fixing pin holes.

29. The socket base of claim 28, wherein said second fixing element further comprises a plurality of second guide pins on a top side thereof.

30. The socket base of claim 29, wherein said second guide pins are used to align the semiconductor devices.

31. The socket base of claim 28, wherein said second fixing element has a connected shape.

32. The test substrate of claim 28, wherein said second fixing element has a pair of disconnected parts.

33. The socket base of claim 32, wherein said second fixing element include two L-shape parts.

34. The socket base of claim 32, wherein said second fixing element include two U-shape parts.

35. The socket base of claim 28, wherein said coupling plate further comprises a plurality of second coupling holes, which are corresponding to the first coupling holes.

36. The socket base of claim 35, wherein said second coupling holes and the first coupling holes are secured by inserting screws therethrough.

37. The socket base of claim 28, wherein said first fixing element further comprises a plurality of third coupling holes for securing to said load board by screws.

38. The socket base of claim 28, wherein said first guide pins are used to align test apparatus.

39. A socket base adaptable to a load board for testing semiconductor devices, comprising:
a pair of second fixing elements, each having a plurality of fixing pins on a bottom side thereof, and a plurality of first coupling holes;
a surface mount matrix, having a plurality of fixing pin holes corresponding to the fixing pins, wherein said second fixing element is secured to said surface mount matrix by respectively inserting the fixing pins into the fixing pin holes; and
a first fixing element, having an opening, a plurality of first guide pins, a plurality of second guide pins, and a plurality of coupling plates, wherein said second fixing element is secured to said first fixing element by the coupling plate.

40. The socket base of claim 39, wherein said first guide pins are used to align test apparatus.

41. The socket base of claim 39, wherein said second guide pins are used to align the semiconductor devices.

42. The test substrate of claim 39, wherein said second fixing element has a pair of disconnected parts.

43. The socket base of claim 42, wherein said second fixing element include two L-shape parts.

44. The socket base of claim 42, wherein said second fixing element include two U-shape parts.

45. The socket base of claim 39, wherein said coupling plate further comprises a plurality of second coupling holes, which are corresponding to the first coupling holes.

46. The socket base of claim 45, wherein said second coupling holes and the first coupling holes are secured by inserting screws therethrough.

47. The socket base of claim 39, wherein said first fixing element further comprises a plurality of third coupling holes for securing to said load board by screws.
